(19) United States
(12) Patent Application Publication
(10) Pub. No.: US 2008/0128826 A1
(43) Pub. Date: Jun. 5, 2008

(54) SEMICONDUCTOR INTEGRATED CIRCUIT AND FABRICATION METHOD FOR THE SAME

(76) Inventors: Shingo Fukamizu, Osaka (JP); Yutaka Nabeshima, Osaka (JP); Hideki Nishino, Osaka (JP)

Correspondence Address: MCDERMOTT WILL & EMERY LLP, 600 13TH STREET, NW, WASHINGTON, DC, 20005-3096, US

(21) Appl. No.: 11/945,605

(22) Filed: Nov. 27, 2007

(30) Foreign Application Priority Data
Dec. 1, 2006 (JP) 2006-325455

(51) Int. Cl. H01L 29/78; H01L 21/4763

(52) U.S. Cl. 257/379; 438/637

(57) ABSTRACT

The semiconductor integrated circuit includes: a power transistor formed on a semiconductor substrate; a plurality of first metal patterns and a plurality of second metal patterns formed right above the power transistor for acting as first and second electrodes of the power transistor; a first bus electrically connected with the first metal patterns; a second bus electrically connected with the second metal patterns; and one contact pad provided for each of the first and second buses. Each of the first and second buses has at least one slit.

### BACKGROUND OF THE INVENTION

The present invention relates to a semiconductor integrated circuit and a fabrication method for the same, and more particularly to a power integrated circuit having a structure permitting execution of wire bonding, as well as probing during testing, at a position right above an active circuit area by use of a POE (pad on element) technique, that is, a technique of placing a pad right above a semiconductor device, and a fabrication method for the same.

In recent years, with the spread of information technology, needs for speedup and power reduction have been growing as performance capabilities of electronic equipment such as computers, information memory devices, mobile phones and digital cameras.

The performance of such electronic equipment is greatly influenced by key semiconductor electronic components such as power supplies, motor drivers and audio amplifiers, and the performance of such semiconductor electronic components is greatly influenced by power integrated circuits incorporating power devices. For this reason, as performance capabilities of semiconductor elements constituting such a power integrated circuit, further speedup, power reduction and quality enhancement have been increasingly requested

As general market requests, wide-range improvement in power devices and circuit characteristics has been desired, in addition to the requests for speedup and power reduction described above. Also, there are a number of demands for a low-cost, reliable structure and method for bonding wires and solder balls at positions right above an active circuit area, and various proposals for such a structure and method have been made.

### Speedup of Semiconductor Integrated Circuit

Impediments to speedup of a semiconductor integrated circuit are delay of MOS transistors themselves and wiring delay caused by interconnects in an overlying layer. Conventionally, the delay of MOS transistors themselves has been reduced by a submicron technology of shortening the gate length. As the delay of MOS transistors themselves has been made smaller, however, the problem of the wiring delay has become more eminent.

To reduce the wiring delay, it has been attempted to adopt an insulating film low in dielectric constant (low dielectric film) as the insulating film interposed between interconnects. However, a low dielectric film attaining a dielectric constant of 3.0 or less is greatly lower in mechanical strength than a silicon oxide film conventionally adopted. This raises problems in the assembly process responsible for packaging of a semiconductor integrated circuit, which follows the diffusion process responsible for circuit formation of the semiconductor integrated circuit, particularly in a wire bonding process.

Hereinafter, specific problems in conventional probe testing and wire bonding will be described.

FIGS. 9A and 9B show simplified cross-sectional views of part of a conventional IC chip 100.

Referring to FIGS. 9A and 9B, an n-type buried region 913 and an n-type well region 917 are formed in a p-type silicon substrate 911. A power transistor 100A composed of gate oxides 930, polysilicon gates 931 and source/drain contact regions 921 is formed on the n-type well region 917. A first inter-level insulator layer 941 is formed to cover the power transistor 100A. First vias 942 are formed through the first inter-level insulator layer 941 to be in contact with the source/drain contact regions 921. Lines SN for source electrodes and lines DN for drain electrodes are formed on the first inter-level insulator layer 941. A second inter-layer insulating film 944 is formed to cover these lines SN and DN. Second vias X are formed through the second inter-level insulator layer 944 to be in contact with the lines SN for source electrodes (likewise, vias (Y) coming into contact with the lines DN for drain electrodes are formed although not shown). A second-layer bus 11 made of a metal layer is formed on the second inter-level insulator layer 944, and a third inter-level insulator layer 947 is formed covering the second-layer bus 11. Third vias X1 are formed through the third inter-level insulator layer 947 to be in contact with the second-layer bus 11 (likewise, vias (Y1) coming into contact with second-layer buses are formed although not shown). Third-layer buses 140C and 150C made of a metal layer are formed on the third inter-level insulator layer 947, and a fourth inter-level insulator layer 950 and a protective overcoat layer 955 are formed on the third-layer buses 140C and 150C. An opening 956 is formed through the fourth inter-layer insulating layer 950, and inside the opening 956 formed are a contact pad 304, a ball 961 and a bonding wire 306.

In the conventional example having the configuration described above, as shown in FIG. 9A, when probe testing or wire bonding is performed on the contact pad 304, an impact load by the probing or the wire bonding causes a warp 972 to occur in the third-layer bus 140C, for example, via the contact pad 304. The warp 972 transfers to the inter-level insulator layer 947 underlying the third-layer bus 140C, deforming the inter-level insulator layer 947 greatly to eventually causes a crack 973 in the inter-level insulator layer 947, as shown FIG. 9B. Such a warp 972 or crack 973 becomes a cause of poor reliability, which is brought by coming off of a pad or peeling off of an interlayer insulating film.

In recent years, semiconductor elements having pads placed on transistors have been developed for the purpose of reducing the size and cost of the semiconductor elements. In such semiconductor elements, if a low dielectric film low in mechanical strength is used as insulating films between interconnects and between layers, the low dielectric film will be deformed with a shock due to probing or wire bonding, and the transistors will become susceptible to the shock. The transistors will therefore be damaged causing quality failure.

Measures against the above problems are suggested in the following patent documents.

In Japanese Patent Gazette No. 2974022 (Patent Document 1), a metal layer is formed right under a pad with an interlayer insulating film therebetween and is connected with the pad via a via. The metal layer therefore receives a shock applied to the interlayer insulating film at wire bonding. Moreover, the via supports the metal layer from being deformed in the direction of application of the shock. In this way, in Patent Document 1, with a pad structure that can compensate reduction in the mechanical strength of the interlayer insulating film formed right under the pad, transistors are prevented from being damaged due to wire bonding.

When copper is used as a metal material, copper interconnects will be formed in a damascene process. In this process, after electrolytic plating of copper, the plated copper is subjected to chemical mechanical polishing (CMP) for flattening. In CMP, a copper pattern having a soft nature will have a phenomenon called dishing in which the center portion thereof is shaved to become very thin if the area of the copper pattern is very large. Moreover, if the area of the copper pattern is made very large while the metal layer is thinned for formation of a fine via pattern in an underlying layer, the copper will partly be shaved off completely by CMP.

In Patent Document 1 described above, the above phenomenon occurs during formation of a second metal, or copper, layer. If a copper pattern becomes thin in its center or copper is partly shaved off completely, as described above, the shock due to wire bonding received by the interlayer insulating film will be great, and this will increase the possibility of occurrence of cracking.

Japanese Patent Gazette No. 3725527 (Patent Document 2) describes a pad structure that can prevent an insulating film and transistors located right under a pad from being damaged due to wire bonding. Specifically, a semiconductor device in Patent Document 2 includes a first electrode made of a conductive layer, an external connection electrode made of a conductive layer formed on the first electrode, and a second electrode of at least one layer formed under the first electrode and connected with the first electrode via a through hole. A number of protrusions are formed at the edges of the second electrode.

By adopting the above structure in which the top-layer metal and an underlying metal layer (lower-layer metal) with an interlayer insulating film interposed therebetween are connected with each other via a via, it is possible to prevent occurrence of deformation or cracking in low dielectric films adopted as inter-wiring films and interlayer films located right under a pad under a shock due to wire bonding. In other words, the top-layer metal, supported by the lower-layer metal, won't be deformed under a shock due to wire bonding. This suppresses the shock due to wire bonding from transferring to the low dielectric film as the interlayer insulating film located right under the pad, and thus can prevent deformation and cracking of the low dielectric film.

Moreover, a number of protrusions are formed at the edges of the lower-layer metal for preventing dishing in CMP that may occur if the lower-layer metal has a large area. This increases the surface area of the lower-layer metal and thus enhances the cohesion of the lower-layer metal with the interlayer film. Transistors are therefore less damaged under a shock due to wire bonding, and also the interlayer insulating film can be prevented from cracking.

As described above, the pad structure adopted in Patent Document 2 can prevent an insulating film and transistors right under a pad from being damaged due to wire bonding, and thus contributes to speedup of semiconductor integrated circuits.

### Power Reduction of Semiconductor Integrated Circuit

An impediment to reduction in the power consumption of semiconductor integrated circuits is implementing a power integrated circuit incorporating a power device utilizing a submicron MOS process with a chip area being made as small as possible while making effective use of the chip area of a semiconductor product. In such a power integrated circuit, a pulse width modulation (PWM) drive technology is generally used in driving the power device for reduction in power consumption. In this PWM drive, an important process technology leading to reduction in power consumption is reducing ON resistance of the power device.

U.S. Patent Application No. 2002-0011674A1 (Patent Document 3) proposes a method of reducing ON resistance of a power device as much as possible using the POE technique. In this patent Document, a power integrated circuit permits execution of wire bonding right above an active circuit area. In this power integrated circuit, by use of the POE technique, a plurality of contact pads are placed right above buses connected to electrodes of a power transistor, and the plurality of contact pads are connected with a lead frame via bonding wires. This structure minimizes the resistance value and current path from the connecting member to the electrodes, and thus permits improvement in the electrical characteristics of the power transistor.

FIG. 10 is a simplified plan view of part of a semiconductor integrated circuit described in Patent Document 3.

As shown in the plan view of FIG. 10, an active area 2 of a power transistor is formed in an IC chip 1. On the active area 2, formed are a first bus 3 connecting all of source electrodes and a second bus 4 connecting all of drain electrodes. Both the first and second buses 3 and 4 are made of sheet-like metal. Three contact pads 5 are formed on each of the first and second buses 3 and 4 to be commonly connected with the bus. The three contact pads 5 on the first bus 3 are placed to be bilaterally symmetric with the three contact pads 5 on the second bus 4. Bonding wires 6 are provided to connect the contact pads 5 with external lead frames 7.

In Patent Document 3 having the above configuration, in which a plurality of contact pads are placed right above buses connected with electrodes of a power transistor and bonding wires connect the plurality of contact pads with a lead frame, a power integrated circuit permitting low ON resistance can be implemented. This contributes to reduction in power consumption as a performance capability of a semiconductor integrated circuit.

### Quality Enhancement of Semiconductor Integrated Circuit

Large impediments to enhancement in the quality of semiconductor integrated circuits are stress problems arising from stress received by semiconductor devices and the like. The stress problems can be roughly classified into ones caused by testing, ones caused by assembly and ones caused by actual operation (application). The following patent documents propose techniques attempting to solve the stress problems by devising the layout.

Japanese Laid-Open Patent Publication No. 53-89688 (Patent Document 4) proposes the followings. In a bend of an aluminum interconnect, in which bending on the substrate surface and bending of a passivation film on both sides of the interconnect overlap, stress concentration especially increases, causing a fracture (cracking) in the passivation film, due to dynamic stress of sealing (mold). As measures against this occurrence, an arc-shaped interconnect corner portion is proposed.

Japanese Laid-Open Patent Publication No. 8-15150 (Patent Document 5) proposes the followings. Strong stress from mold resin is applied to the four corners of a chip, and this causes cracking in a passivation film at and around a guard ring. As measures against this occurrence, it is proposed to provide an array of slits or holes along the corners so as to restrict the actual width of a conductive film of the guard ring at the corners.

As for a stress problem caused by application, Japanese Laid-Open Patent Publication No. 7-58710 (Patent Document 6) proposes the followings. A wide interconnect for supplying a power supply voltage has large stress due to a difference in thermal expansion that is greater as the width is larger, and the stress is posed to an underlying interconnect. Therefore, even though the underlying interconnect has a line width large enough to hold sufficient strength, disconnection may occur due to stress migration. As measures against this occurrence, it is proposed to provide slits sufficiently short compared with the length of the connecting portion in the wide interconnect in a line along the direction of extension of the interconnect, and place a plurality of such lines of slits in parallel with each other.

Patent Documents 4, 5 and 6 described above intend to solve a stress problem caused by assembly and a stress problem caused by actual operation (application) by devising layouts in semiconductor devices, and thus contribute to attainment of quality enhancement as a performance capability of semiconductor integrated circuits.

However, in the configurations disclosed in Patent Documents 3 to 6 described above, occurrence of warping increases in the vicinity of the top-layer wide bus formed under a contact pad due to stress caused by a load on the contact pad at probing or bonding, and cracking occurs in an insulating film. Cracking occurs because of the increase of the warping in the vicinity of the top-layer wide bus under the contact pad and decrease in the strength of the insulating film under the contact pad. The top-layer wide bus and the insulating film under the contact pad fail to absorb the stress caused by the load applied to the contact pad. If a crack produced reaches an underlying insulating film, an underlying semiconductor element will be damaged.

In other words, because of the failure of relieving the mechanical dynamic stress due to probe testing or wire bonding transferred from the contact pad placed right above a power transistor, warping occurs in the vicinity of a wide large bus, and thus cracking occurs in an insulating film in the vicinity of the pad and the top-layer wide bus.

### SUMMARY OF THE INVENTION

An object of the present invention is providing a semiconductor integrated circuit having a configuration capable of relieving mechanical dynamic stress due to probing during testing and mechanical dynamic stress due to wire bonding during assembly and a fabrication method for such a semiconductor integrated circuit. With such a configuration, occurrence of warping in the vicinity of a bus, which may cause a damage or stress on a power transistor, is prevented and thus occurrence of cracking in the vicinity of a pad is reduced, whereby a highly reliable semiconductor integrated circuit that attains reduction in power consumption and saving in chip area is provided.

The semiconductor integrated circuit of the present invention includes: an integrated power transistor formed on a semiconductor substrate; an interlayer insulating film formed on the power transistor; at least one or more first metal patterns made of a first metal layer formed inside the interlayer insulating film at a position right above the power transistor, for acting as a first electrode of the power transistor; at least one or more second metal patterns made of the first metal layer for acting as a second electrode of the power transistor; a single first bus made of a second metal layer formed inside the interlayer insulating film at a position right above the first metal layer, the first bus being electrically connected with the at least one or more first metal patterns; a single second bus made of the second metal layer, the second bus being electrically connected with the at least one second metal patterns; and one contact pad provided for each of the first bus and the second bus, wherein each of the first bus and the second bus has at least one slit.

According to the semiconductor integrated circuit described above, since stress applied in the bonding process or during probe testing can be absorbed, the first and second buses can be prevented from warping, and thus occurrence of cracking in the vicinity of the contact pads can be prevented. It is therefore possible to place pads right above the power transistor, and thus a highly reliable semiconductor integrated circuit can be implemented. Moreover, by placing power-supply contact pads right above the power transistor, precious silicon real estate can be saved. With reduction of the silicon area consumed in the entire circuit design, the cost of the IC chip can be reduced. In this way, saving in IC chip area and reduction in IC cost can be attained.

In the semiconductor integrated circuit described above, at least one or more contact pads may be provided for each of the first bus and the second bus.

With the above configuration, the current route flowing to the power transistor can be clearly defined, and the current flowing to the power transistor can be optimized. Therefore, the allowable current value of the power transistor as a whole can be increased, and as a result, the reliability of the semiconductor integrated circuit is improved.

In the semiconductor integrated circuit described above, the power transistor may be divided into a plurality of parts with an isolation layer.

With the above configuration, in which the divided power transistors are surrounded with an isolation layer, latch- or parasitic-related malfunctions become less likely to occur, and thus the reliability of the semiconductor integrated circuit is improved.

In the semiconductor integrated circuit described above, the slit may be formed at edges of each of the first bus and the second bus.

With the above configuration, since stress applied in the bonding process or during probe testing can be absorbed, occurrence of cracking can be prevented. As a result, pads can be placed right above the power transistor, and thus a highly reliable semiconductor integrated circuit with a small chip area can be implemented.

In the semiconductor integrated circuit described above, the slit may be formed inside each of the first bus and the second bus.

With the above configuration, since stress applied in the bonding process or during probe testing can be absorbed, occurrence of cracking can be prevented. As a result, pads can be placed right above the power transistor, and thus a highly reliable semiconductor integrated circuit with a small chip area can be implemented. Also, the current route flowing to the power transistor can be clearly defined.

In the semiconductor integrated circuit described above, a plurality of slits may be formed at edges of and inside each of the first bus and the second bus.

With the above configuration, substantially the same effect as that obtained when slits are placed at edges or inside described above can be obtained. However, placing slits at edges or inside described above is better in reduction in ON resistance.

In the semiconductor integrated circuit described above, each of the first bus and the second bus may be divided into a plurality of parts with the slit, one contact pad may be formed on each of the plurality of divided buses, and the size of the power transistor may be equal to or greater than the size of each of the contact pads on each of the plurality of divided buses as is viewed from top.

With the above configuration, stress that may be applied to a large-size bus is dissipated to slit-divided buses. This can suppress occurrence of warping that may occur in a large-area bus susceptive to stress if there is such a bus, and reduce stress on the entire power transistor. As a result, the reliability of the semiconductor integrated circuit is improved.

The fabrication method for a semiconductor integrated circuit of the present invention includes the steps of: forming an integrated power transistor on a semiconductor substrate; forming a first interlayer insulating film on the power transistor; depositing a first metal layer right above the power transistor via the first interlayer insulating film and then patterning the first metal layer, to form at least one or more first metal patterns acting as a first electrode of the power transistor and at least one or more second metal patterns acting as a second electrode of the power transistor; forming a second interlayer insulating film on the first interlayer insulating film so as to cover the at least one or more first metal patterns and the at least one or more second metal patterns; depositing a second metal layer right above the first metal layer via the second interlayer insulating film and then patterning the second metal layer, to form a single first bus electrically connected with the at least one or more first metal patterns and having at least one strip and a single second bus electrically connected with the at least one or more second metal patterns and having at least one strip; forming a third interlayer insulating film on the second interlayer insulating film so as to cover the first bus and the second bus; forming one opening through the third interlayer insulating film for each of the first bus and the second bus so as to expose the first bus and the second bus; placing a contact pad on each of the first bus and the second bus exposed in the opening; and attaching at least one connection member to the contact pad.

According to the fabrication method for a semiconductor integrated circuit described above, the semiconductor integrated circuit having the effect described above can be implemented.

In the fabrication method described above, the step of forming one opening may include the step of forming at least one or more openings through the third interlayer insulating film for each of the first bus and the second bus so as to expose the first bus and the second bus.

According to the semiconductor integrated circuit and the fabrication method for the same of the present invention, since stress applied in the bonding process or during probe testing can be absorbed, warping of the first and second buses can be prevented, and thus occurrence of cracking in the vicinity of the contact pads can be prevented. It is therefore possible to place pads right above the power transistor, and thus a highly reliable semiconductor integrated circuit can be implemented. Moreover, by placing power-supply contact pads right above the power transistor, precious silicon real estate can be saved. With reduction of the silicon area consumed in the entire circuit design, the cost of the IC chip can be reduced. In this way, saving in IC chip area and reduction in IC cost can be attained.

### BRIEF DESCRIPTION OF THE DRAWINGS

FIG. 1A is a simplified plan view diagrammatically showing part of an IC chip, as a portion of a semiconductor integrated circuit of Embodiment 1 of the present invention, having two single buses, each of which has one contact pad thereon and has slits formed at the upper, lower, left and right edges thereof, and FIG. 1B is a simplified plan view diagrammatically showing part of an IC chip, as a portion of a semiconductor integrated circuit of Embodiment 1 of the present invention, having two single buses, each of which has a plurality of contact pads thereon and has slits formed at the upper, lower, left and right edges thereof.

FIG. 2 is a simplified plan view diagrammatically showing part of an IC chip, as a portion of a semiconductor integrated circuit of Embodiment 1 of the present invention, illustrating the positional relationship among a bus metal layer (third-layer buses) that is to be two single buses having slits formed at the upper, lower, left and right edges thereof, a metal layer (second-layer buses) underlying the above metal layer, which is to be lines for source and drain electrodes, and vias.

FIG. 3 is a simplified plan view diagrammatically showing part of an IC chip, as a portion of a semiconductor integrated circuit of Embodiment 1 of the present invention, illustrating the positional relationship among the bus metal layer (third-layer buses) that is to be two single buses having slits formed at the upper, lower, left and right edges thereof, the metal layer (second-layer buses) underlying the above metal layer, which is to be lines for source and drain electrodes, a metal layer (first-layer buses) further underlying the above metal layer, which is to be source and drain electrodes, and vias.

FIG. 4 is a cross-sectional view of a portion of a semiconductor integrated circuit of Embodiment 1 of the present invention, taken along line II-II in FIG. 1B.

FIG. 5A is a simplified plan view diagrammatically showing part of an IC chip, as a portion of a semiconductor integrated circuit of Embodiment 2 of the present invention, having two single buses, each of which has one contact pad thereon and has slits formed therein, and FIG. 5B is a simplified plan view diagrammatically showing part of an IC chip, as a portion of a semiconductor integrated circuit of Embodiment 2 of the present invention, having two single buses, each of which has a plurality of contact pads thereon and has slits formed therein.

FIG. 6A is a simplified plan view diagrammatically showing part of an IC chip, as a portion of a semiconductor integrated circuit of Embodiment 3 of the present invention, having two single buses, each of which has one contact pad thereon and has slits formed at edges thereof and also slits formed therein, and FIG. 6B is a simplified plan view diagrammatically showing part of an IC chip, as a portion of a semiconductor integrated circuit of Embodiment 3 of the present invention, having two single buses, each of which has a plurality of contact pads thereon and has slits formed at edges thereof and also slits formed therein.

FIG. 7 is a simplified plan view diagrammatically showing part of an IC chip, as a portion of a semiconductor integrated circuit of Embodiment 4 of the present invention, in which a bus metal layer is divided into a plurality of buses with slits, one contact pad is placed on each bus, and each of three divided power transistor regions is surrounded with an isolation layer.

FIG. 8 is a simplified plan view diagrammatically showing part of an IC chip, as a portion of the semiconductor integrated circuit of Embodiment 4 of the present invention, illustrating the positional relationship among a bus metal layer (third-layer buses) divided into a plurality of buses with slits, a metal layer (second-layer buses) underlying the above bus metal layer, which is to be lines for source and drain electrodes, and vias.

FIGS. 9A and 9B are cross-sectional views for demonstrating the problems in the conventional semiconductor integrated circuits, wherein FIG. 9A shows a state that an interlayer insulating film right under a pad has been greatly deformed, and FIG. 9B shows a state that a crack has occurred in the interlayer insulating film right under the pad.

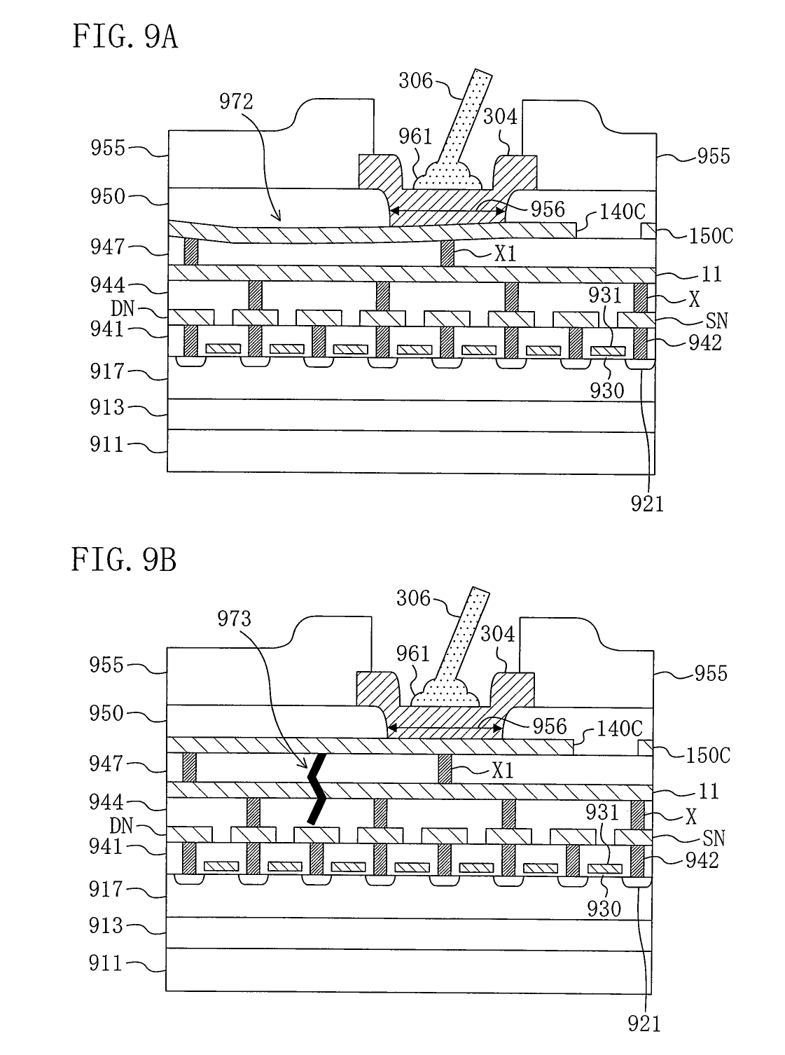

FIG. 10 is a simplified plan view diagrammatically showing a portion of an IC chip having power transistors, in which a plurality of contact pads are placed on each bus metal layer to be commonly connected with the bus metal layer.

### DESCRIPTION OF THE PREFERRED EMBODIMENTS

### Embodiment 1

Hereinafter, semiconductor integrated circuits and fabrication methods for the same of Embodiment 1 of the present invention will be described with reference to the relevant drawings.

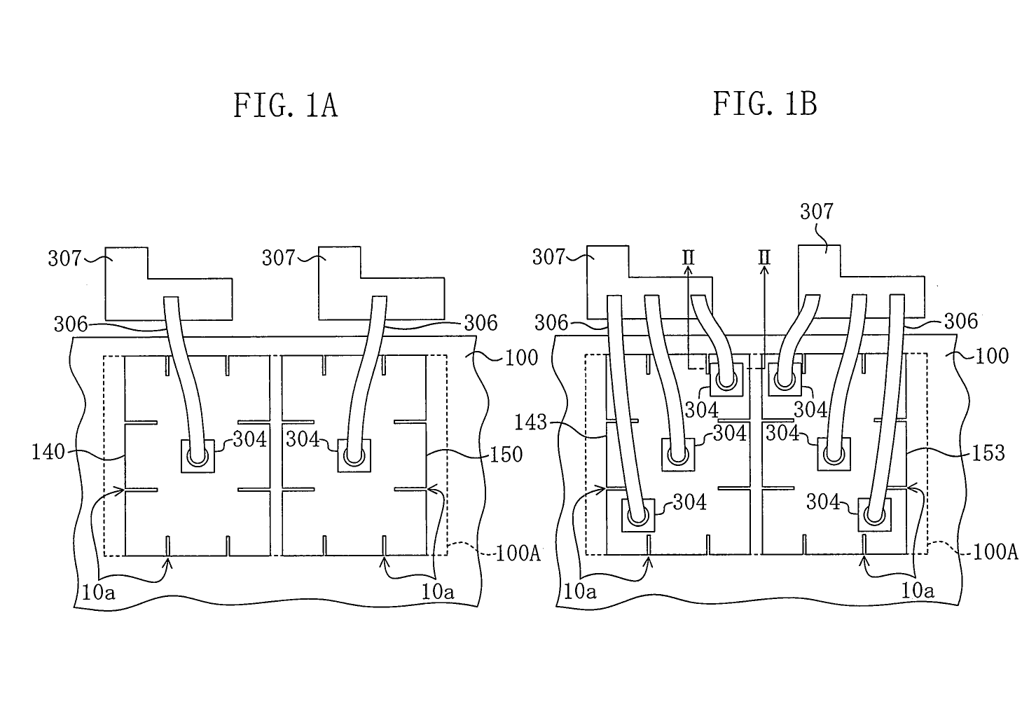

FIGS. 1A and 1B are simplified plan views of part of semiconductor integrated circuits of Embodiment 1 of the present invention.

As shown in the plan view of FIG. 1A, an active area 100A of a power transistor surrounded with an isolation layer is formed in an IC chip 100. On the active area 100A, a single first bus 140 and a single second bus 150 are formed to cover source and drain regions of the power transistor. The first bus 140, which is in a topmost metal layer (third metal layer) made from sheet-like metal, is connected to source electrodes. Likewise, the second bus 150, which is also in the topmost metal layer (third metal layer) made from sheet-like metal, is connected to drain electrodes. One contact pad 304 is formed on each of the first and second buses 140 and 150. One external lead frame 307 (power supply) is provided for each of the first and second buses 140 and 150, and a bonding wire 306 is provided to connect the lead frame 307 with the contact pad 304.

Also, as shown in FIG. 1A, slits 10a are formed at the upper, lower, left and right edges, as is viewed from the figure, of each of the first and second buses 140 and 150. Having these slits, stress caused by a load applied to the contact pad 304 at wire bonding and at probing during testing can be relieved.

Likewise, as shown in the plan view of FIG. 1B, an active area 100A of a power transistor surrounded with an isolation layer is formed in an IC chip 100. On the active area 100A, a single first bus 143 and a single second bus 153 are formed to cover source and drain regions of the power transistor. The first bus 143, which is in a topmost metal layer (third metal layer) made from sheet-like metal, is connected to source electrodes. Likewise, the second bus 153, which is also in the topmost metal layer (third metal layer) made from sheet-like metal, is connected to drain electrodes. Three contact pads 304 are formed on each of the first and second buses 143 and 153. One external lead frame 307 (power supply) is provided for each of the first and second buses 143 and 153, and a bonding wire 306 is provided to connect the lead frame 307 with each contact pad 304.

Also, as shown in FIG. 1B, slits 10a are formed at the upper, lower, left and right edges, as is viewed from the figure, of each of the first and second buses 143 and 153. Having these slits, stress caused by load applied to the contact pads 304 at wire bonding and at probing during testing can be relieved.

Next, the positional relationship among the buses as the topmost metal layer and underlying two metal layers in the semiconductor integrated circuits shown in FIGS. 1A and 1B described above will be described. Note that although the semiconductor integrated circuit shown in FIG. 1A is used as an example in the following description, the relationship will also apply to the semiconductor integrated circuit shown in FIG. 1B.

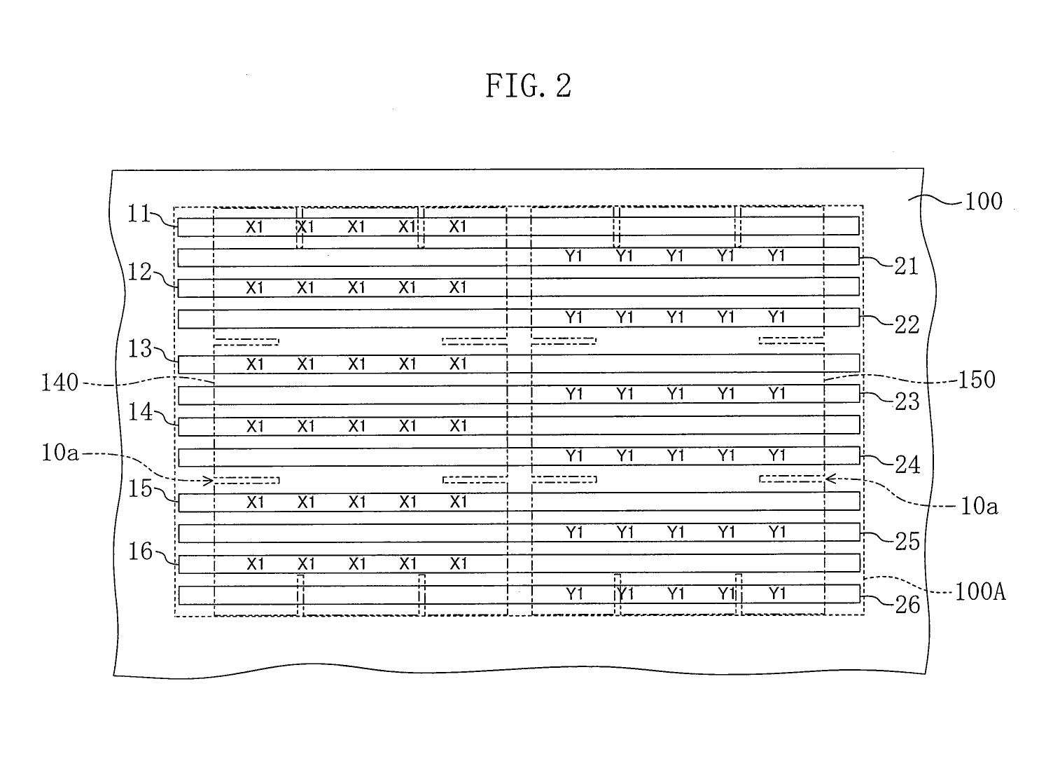

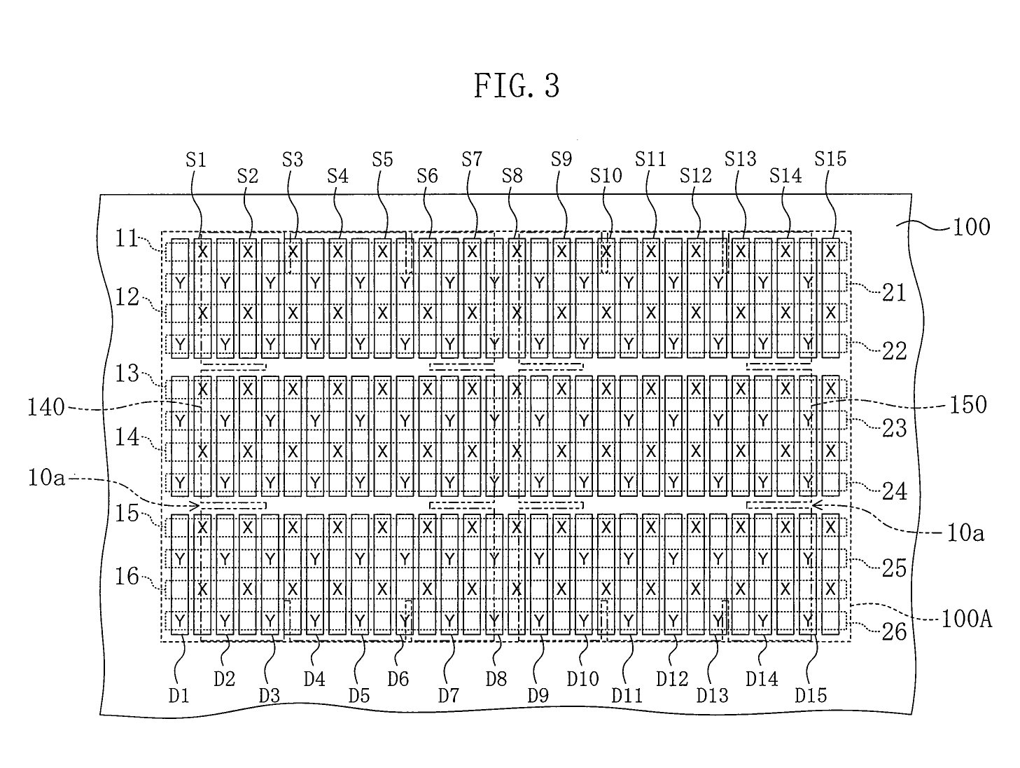

FIGS. 2 and 3 are plan views diagrammatically showing the positional relationships among the buses 140 and 150 shown in FIG. 1A and the underlying metal layers. Note that the buses 140 and 150 are shown by phantom lines in FIGS. 2 and 3, and the second-layer buses are shown by phantom lines in FIG. 3.

As shown in FIG. 2, under the buses 140 and 150 as the third-layer buses in this embodiment, formed alternately are source lines 11, 12, 13, 14, 15 and 16 (first metal patterns) and drain lines 21, 22, 23, 24, 25 and 26 (second metal patterns), both as the second-layer buses (second metal layer), which are arranged in lateral elongated stripes parallel to one another at a fixed pitch. The third-layer bus 140 is connected to the source lines 11, 12, 13, 14, 15 and 16 as the second-layer buses via a plurality of metal-filled vias X1. Likewise, the third-layer bus 150 is connected to the drain lines 21, 22, 23, 24, 25 and 26 via a plurality of metal-filled vias Y1.

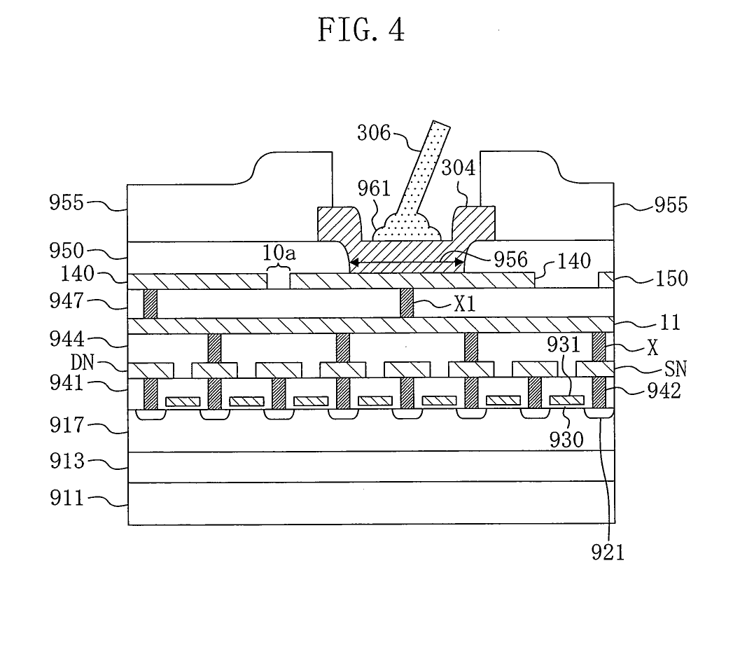

As shown in FIG. 3, under the source and drain lines 11 to 16 and 21 to 26 as the second-layer buses, formed alternately are lines S1 to S15 for source electrode (first metal patterns) and lines D1 to D15 for drain electrode (second metal patterns), both as the first-layer buses (first metal layer), which are arranged orthogonal to the second-layer buses and also arranged in vertical elongated stripes parallel to one another at a fixed pitch. Each of the lines S1 to S15 for source electrode as the first-layer buses are electrically connected to the source lines 11 to 16 as the second-layer buses via a plurality of metal-filled vias X. Likewise, each of the lines D1 to D15 for drain electrode as the first-layer buses are electrically connected to the drain lines 21 to 26 as the second-layer buses via a plurality of metal-filled vias Y. Note that FIGS. 1A, 1B, 2, and 3 are views for mainly demonstrating the positional relationship among the first-layer to third-layer buses, vias, contact pads and bonding wires formed on the semiconductor substrate. As for interlayer insulating films not shown formed between buses (as those shown in FIG. 4 to be described later), openings and the like, description will be made in a specific example shown in FIG. 4.

FIG. 4 is a cross-sectional view taken along line II-II in FIG. 1B, showing part of the cross-sectional structure of a semiconductor integrated circuit of this embodiment. As for the cross-sectional structure of the semiconductor integrated circuit shown in FIG. 1A, no specific description will be made, but it should be easily conceived from the following description on FIG. 1B.

As shown in FIG. 4, an n-type buried region 913, an n-type well region 917, source/drain contact regions 921, gate oxides 930 and polysilicon gates 931 are formed on a p-type silicon substrate 911. A first inter-level insulator layer 941 is formed covering these elements. First vias 942 are formed through the first inter-level insulator layer 941 to reach the source/drain contact regions 921. Lines SN for source electrodes and lines DN for drain electrodes (both first-layer buses) made of a metal layer are formed on the first inter-level insulator layer 941. A second inter-level insulator layer 944 is formed to cover the line SN for source electrodes and DN for drain electrodes. Second vias X are formed through the second inter-level insulator layer 944 to be in contact with the lines SN for source electrodes. Although not shown, vias contacting with the lines DN for drain electrodes are also formed through the second inter-level insulator layer 944. A source line (second-layer bus) 11, for example, made of a metal layer is formed on the second inter-level insulator layer 944 (a drain line (second-layer bus) is also formed in a similar manner in a section not shown). A third inter-level insulator layer 947 is formed covering the source lines and the drain lines not shown. Third vias X1 are formed through the third inter-level insulator layer 947 to be in contact with the source line 11 (likewise, vias are also formed to be in contact with a drain line in a section not shown). Third-layer buses 140 and 150 made of a metal layer are formed on the third inter-level insulator layer 947. Slits 10a are formed in the third-layer buses 140 and 150 (no slit formed in the bus 150 is shown). A fourth inter-level insulator layer 950 is formed covering the buses 140 and 150. An opening 956 is formed through the fourth inter-layer insulating layer 950, and a contact pad 304 is formed inside the opening 956. A protective overcoat layer 955 is formed on the fourth inter-layer insulating layer 950 exposing the contact pad 304. A ball 961 and a bonding wire 306 are formed on the contact pad 304.

With the above configuration, the stress received by the contact pad 304, that is, the impact load applied at probing during testing or wire bonding is dissipated with the slits 10a provided at the top-layer buses 140 and 150.

The difference between the semiconductor integrated circuits shown in FIGS. 1A and 1B is that a plurality of contact pads 304 are provided for each of the first and second buses 143 and 153 in FIG. 1B. The configuration of FIG. 1B increases the number of bonding wires 306 permitting increase of the allowable current value. With this configuration, therefore, it is possible to eliminate the constraints related to the bonding wires 306 in attainment of a large-current power transistor, to thereby reduce the resistance component of the bonding wires 306 in the entire resistance of the power transistor. In this way, by reducing the resistance of the power transistor, it is possible to further increase the allowable current value of the power transistor as a whole.

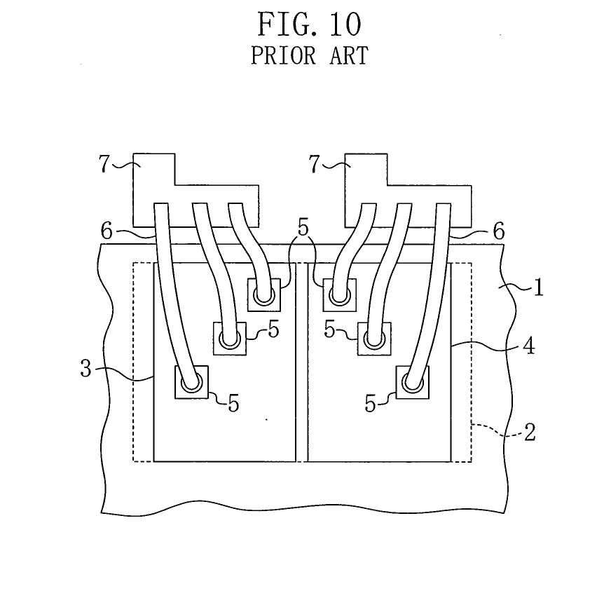

Also, as is apparent from the comparison of the semiconductor integrated circuits shown in FIGS. 1A and 1B with the conventional semiconductor integrated circuit shown in FIG. 10, the slits 10a are provided at edges of the top-layer buses (140, 150 in FIG. 1A and 143, 153 in FIG. 1B) in the semiconductor integrated circuits of this embodiment shown in FIGS. 1A and 1B while nothing special is devised in the top-layer buses in the power transistor in FIG. 10. This difference in configuration permits the semiconductor integrated circuits of this embodiment to produce the following effect that is unattainable in the conventional case. That is, since the stress applied at wire bonding or probing during testing is dissipated with the slits 10a, it is possible to suppress occurrence of warping in the vicinity of the top-layer buses formed under the contact pads 304 and thus prevent occurrence of cracking in an insulating film in the vicinity of the contact pads 304. As a result, the reliability of the semiconductor integrated circuit can be improved.

In the semiconductor integrated circuits shown in FIGS. 1A and 1B, the slits 10a were placed at the upper, lower, left and right edges of the buses (140, 150 in FIG. 1A and 143, 153 in FIG. 1B) as is viewed from the figures. Although not specifically specified, the slits 10a may be placed at either the upper and lower edges or the left and right edges. In this case, also, the stress applied at wire bonding or at probing during testing can be dissipated with the slits 10a.

As described above, in the semiconductor integrated circuit of Embodiment 1 of the present invention, the slits formed at the top-layer buses can absorb the stress applied in the bonding process or during probe testing. It is therefore possible to prevent occurrence of warping at the wide top-layer buses and thus prevent occurrence of cracking in the vicinity of the pads. This permits placement of a contact pad right above a power transistor, and thus a highly reliable semiconductor integrated circuit can be implemented.

Moreover, by placing a power-supply contact pad right above a power transistor, precious silicon real estate can be saved. By reducing the silicon area consumed in the entire circuit design, the cost of the IC chip can be reduced. In other words, saving in IC chip area and reduction in IC cost can be attained.

### Embodiment 2

Hereinafter, semiconductor integrated circuits and fabrication methods for the same of Embodiment 2 of the present invention will be described with reference to the relevant drawings.

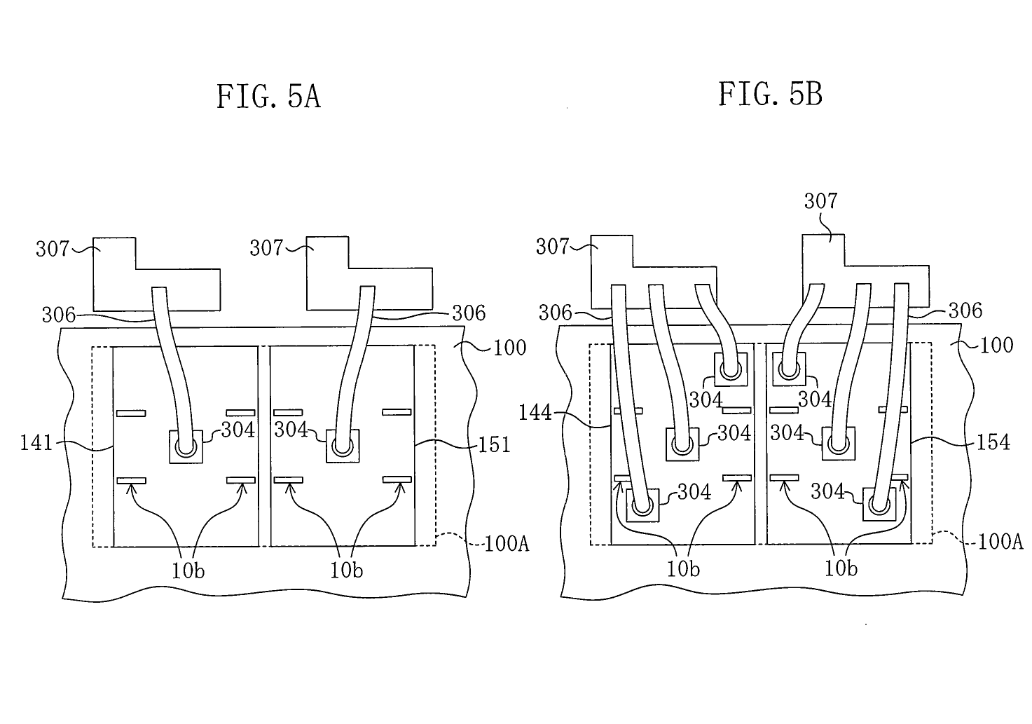

FIGS. 5A and 5B are simplified plan views of part of semiconductor integrated circuits of Embodiment 1 of the present invention.

As shown in the plan view of FIG. 5A, an active area 100A of a power transistor surrounded with an isolation layer is formed in an IC chip 100. On the active area 100A, a single first bus 141 and a single second bus 151 are formed to cover source and drain regions of the power transistor. The first bus 141, which is in a topmost metal layer (third metal layer) made from sheet-like metal, is connected to source electrodes. Likewise, the second bus 151, which is also in the topmost metal layer (third metal layer) made from sheet-like metal, is connected to drain electrodes. One contact pad 304 is formed on each of the first and second buses 141 and 151. One external lead frame 307 (power supply) is provided for each of the first and second buses 141 and 151, and a bonding wire 306 is provided to connect the lead frame 307 with the contact pad 304.

Also, as shown in FIG. 5A, slits 10b are formed inside each of the first and second buses 141 and 151 at positions near the contact pad 304. Having these slits, stress caused by load applied to the contact pad 304 at wire bonding and at probing during testing can be relieved.

Likewise, as shown in the plan view of FIG. 5B, an active area 100A of a power transistor surrounded with an isolation layer is formed in an IC chip 100. On the active area 100A, a single first bus 144 and a single second bus 154 are formed to cover source and drain regions of the power transistor. The first bus 144, which is in a topmost metal layer (third metal layer) made from sheet-like metal, is connected to source electrodes. Likewise, the second bus 154, which is also in the topmost metal layer (third metal layer) made from sheet-like metal, is connected to drain electrodes. Three contact pads 304 are formed on each of the first and second buses 144 and 154. One external lead frame 307 (power supply) is provided for each of the first and second buses 144 and 154, and a bonding wire 306 is provided to connect the lead frame 307 with each contact pad 304.

Also, as shown in FIG. 5B, slits 10b are formed inside each of the first and second buses 144 and 154 at positions near the contact pads 304. Having these slits, stress caused by load applied to the contact pads 304 at wire bonding and at probing during testing can be relieved.

The other cross-sectional configuration of the semiconductor integrated circuits shown in FIGS. 5A and 5B, as well as the underlying configuration that is not shown in FIGS. 5A and 5B, will be easily conceived from the description in Embodiment 1, and thus description thereof is omitted here.

The difference between the semiconductor integrated circuits shown in FIGS. 5A and 5B is that a plurality of contact pads 304 are provided for each of the single first and second buses 144 and 154 in FIG. 5B. The configuration of FIG. 5B increases the number of bonding wires 306 permitting increase of the allowable current value. With this configuration, therefore, it is possible to eliminate the constraints related to the bonding wires 306 in attainment of a large-current power transistor, to thereby reduce the resistance component of the bonding wires 306 in the entire resistance of the power transistor. In this way, by reducing the resistance of the power transistor, it is possible to further increase the allowable current value of the power transistor as a whole.

Also, as is apparent from the comparison of the semiconductor integrated circuits shown in FIGS. 5A and 5B with the conventional semiconductor integrated circuit shown in FIG. 10, the slits 10b are provided inside the top-layer buses (141, 151 in FIG. 5A and 144, 154 in FIG. 5B) in the semiconductor integrated circuits of this embodiment shown in FIGS. 5A and 5B while nothing special is devised in the top-layer buses in the power transistor in FIG. 10. This difference in configuration permits the semiconductor integrated circuits of this embodiment to produce the following effect that is unattainable in the conventional case. That is, since the stress applied at wire bonding or at probing during testing is dissipated with the slits 10b, it is possible to suppress occurrence of warping in the vicinity of the top-layer buses formed under the contact pads 304 and thus prevent occurrence of cracking in an insulating film in the vicinity of the contact pads 304. As a result, the reliability of the semiconductor integrated circuit can be improved.

In the semiconductor integrated circuits shown in FIGS. 5A and 5B, four slits 10b were placed inside each of the buses (141, 151 in FIG. 5A and 144, 154 in FIG. 5B) at positions near the contact pad 304. The number of slits is not limited to this, and in cases of having other numbers of slits, also, the stress applied at wire bonding or at probing during testing can be dissipated with the slits.

As described above, in the semiconductor integrated circuit of Embodiment 2 of the present invention, with the placement of slits inside the top-layer buses (141, 151 in FIG. 5A and 144, 154 in FIG. 5B), the stress applied at wire bonding and at probe during testing can be dissipated. It is therefore possible to prevent occurrence of warping in the vicinity of the top-layer buses formed under the contact pads 304 and thus prevent occurrence of cracking in an insulating film in the vicinity of the contact pads 304.

### Embodiment 3

Hereinafter, semiconductor integrated circuits and fabrication methods for the same of Embodiment 3 of the present invention will be described with reference to the relevant drawings.

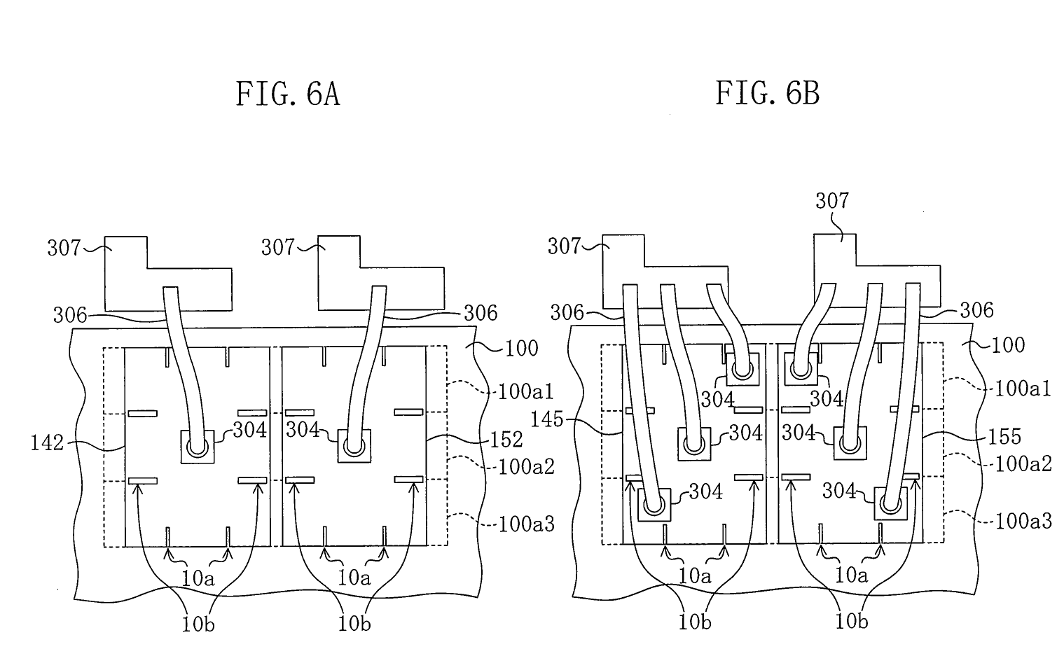

FIGS. 6A and 6B are simplified plan views of part of semiconductor integrated circuits of Embodiment 3 of the present invention.

As shown in the plan view of FIG. 6A, active areas 100a1, 100a2 and 100a3 of a power transistor divided with an isolation layer are formed in an IC chip 100. On the active areas 100a1, 100a2 and 100a3, a single first bus 142 and a single second bus 152 are formed to cover source and drain regions of the power transistor. The first bus 142, which is in a topmost metal layer (third metal layer) made from sheet-like metal, is connected to source electrodes. Likewise, the second bus 152, which is also in the topmost metal layer (third metal layer) made from sheet-like metal, is connected to drain electrodes. One contact pad 304 is formed on each of the first and second buses 142 and 152. One external lead frame 307 (power supply) is provided for each of the first and second buses 142 and 152, and a bonding wire 306 is provided to connect the lead frame 307 with the contact pad 304.

Also, as shown in FIG. 6A, slits 10a are formed at upper and lower edges of each of the first and second buses 142 and 152, as is viewed from the figure, and also slits 10b are formed inside each of the first and second buses 142 and 152 at positions near the contact pad 304. Having these slits, stress caused by load applied to the contact pad 304 at wire bonding and at probing during testing can be relieved.

Likewise, as shown in the plan view of FIG. 6B, active areas 100a1, 100a2 and 100a3 of a power transistor divided with an isolation layer are formed in an IC chip 100. On the active areas 100a1, 100a2 and 100a3, a single first bus 145 and a single second bus 155 are formed to cover source and drain regions of the power transistor. The first bus 145, which is in a topmost metal layer (third metal layer) made from sheet-like metal, is connected to source electrodes. Likewise, the second bus 155, which is also in the topmost metal layer (third metal layer) made from sheet-like metal, is connected to drain electrodes. Three contact pads 304 are formed on each of the first and second buses 145 and 155. One external lead frame 307 (power supply) is provided for each of the first and second buses 145 and 155, and a bonding wire 306 is provided to connect the lead frame 307 with each contact pad 304.

Also, as shown in FIG. 6B, slits 10a are formed at upper and lower edges of each of the first and second buses 145 and 155, as is viewed from the figure, and also slits 10b are formed inside each of the first and second buses 145 and 155 at positions near the contact pads 304. Having these slits, stress caused by load applied to the contact pads 304 at wire bonding and at probing during testing can be relieved.

The other cross-sectional configuration of the semiconductor integrated circuits shown in FIGS. 6A and 6B, as well as the underlying configuration that is not shown in FIGS. 6A and 6B, will be easily conceived from the description in Embodiment 1, and thus description thereof is omitted here.

The difference between the semiconductor integrated circuits shown in FIGS. 6B and 6A is that a plurality of contact pads 304 are provided for each of the single first and second buses 145 and 155 in FIG. 6B. The configuration of FIG. 6B increases the number of bonding wires 306, permitting increase of the allowable current value. With this configuration, therefore, it is possible to eliminate the constraints related to the bonding wires 306 in attainment of a large-current power transistor, to thereby reduce the resistance component of the bonding wires 306 in the entire resistance of the power transistor. In this way, by reducing the resistance of the power transistor, it is possible to further increase the allowable current value of the power transistor as a whole.

Also, as is apparent from the comparison of the semiconductor integrated circuits shown in FIGS. 6A and 6B with the conventional semiconductor integrated circuit shown in FIG. 10, the slits 10a are provided at edges of the top-layer buses (142, 152 in FIG. 6A and 145, 155 in FIG. 6B) and also the slits 10b are provided inside the top-layer buses in the semiconductor integrated circuits of this embodiment shown in FIGS. 6A and 6B while nothing special is devised in the top-layer buses in the power transistor in FIG. 10. This difference in configuration permits the semiconductor integrated circuits of this embodiment to produce the following effect that is unattainable in the conventional case. That is, since the stress applied at wire bonding or at probing during testing is dissipated with the slits 10a and 10b, it is possible to suppress occurrence of warping in the vicinity of the top-layer buses formed under the contact pads 304 and thus prevent occurrence of cracking in an insulating film in the vicinity of the contact pads 304. As a result, the reliability of the semiconductor integrated circuit can be improved.

In the semiconductor integrated circuits shown in FIGS. 6A and 6B, the placement and number of slits in the single buses (142, 152 in FIG. 6A and 145, 155 in FIG. 6B) are not restrictive and are similar to those described in Embodiments 1 and 2 above.

As described above, in the semiconductor integrated circuit of Embodiment 3 of the present invention, with the placement of the slits 10a and 10b at edges of and inside the top-layer buses (142, 152 in FIG. 6A and 145, 155 in FIG. 6B), the stress applied at wire bonding and at probing during testing can be dissipated. It is therefore possible to prevent occurrence of warping in the vicinity of the top-layer buses formed under the contact pads 304 and thus prevent occurrence of cracking in an insulating film in the vicinity of the contact pads 304.

Moreover, the power transistor is divided along the direction of the slits 10b formed inside the top-layer buses (142, 152 in FIG. 6A and 145, 155 in FIG. 6B) with an isolation layer. In other words, the entire power transistor is composed of three small power transistors, and each of the three small power transistors is surrounded with the isolation layer. With this configuration, latch- or parasitic-related malfunctions become less likely to occur, and thus the reliability of the semiconductor integrated circuit is improved.

### Embodiment 4

Hereinafter, a semiconductor integrated circuit and a fabrication method for the same of Embodiment 4 of the present invention will be described with reference to the relevant drawing.

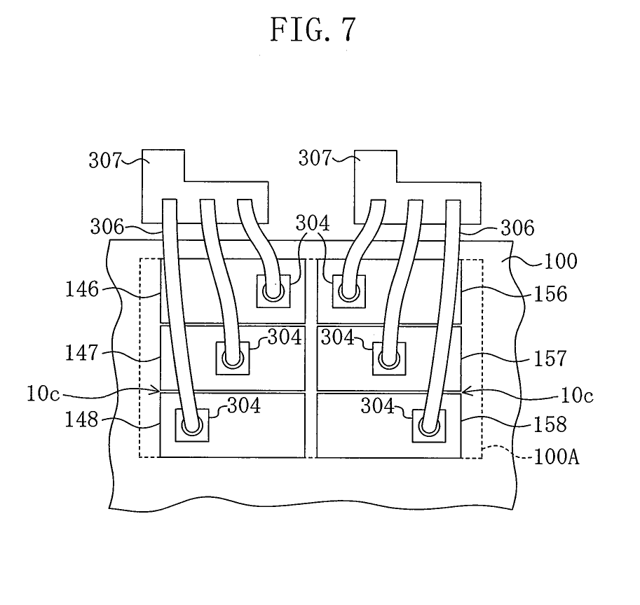

FIG. 7 is a simplified plan view of part of a semiconductor integrated circuit of Embodiment 4 of the present invention.

As shown in the plan view of FIG. 7, an active area 100A of a power transistor surrounded with an isolation layer is formed in an IC chip 100. On the active area 100A, buses 146 to 148 and buses 156 to 158 are formed to cover source and drain regions of the power transistor. The buses 146 to 148, which are in a topmost metal layer (third metal layer) made from sheet-like metal, are connected with source electrodes. The buses 146 to 148 are obtained by dividing a bus equally with slits 10c. Likewise, the buses 156 to 158, which are in the topmost metal layer (third metal layer) made from sheet-like metal, are connected with drain electrodes. The buses 156 to 158 are obtained by dividing a bus equally with slits 10c. One contact pad 304 is formed on each of the buses 146 to 148 and 156 to 158. One external lead frame 307 (power supply) is provided for the buses 146 to 148, and one external lead frame 307 (power supply) is provided for the buses 156 to 158. A bonding wire 306 is provided to connect the lead frame 307 with each contact pad 304.

Next, the positional relationship among the buses as the topmost metal layer and underlying two metal layers in the semiconductor integrated circuits shown in FIG. 7 described above will be described. The positional relationship between second-layer buses and first-layer buses is roughly the same as that shown in FIG. 3 except for the position of the top-layer buses, and thus description thereof is omitted here.

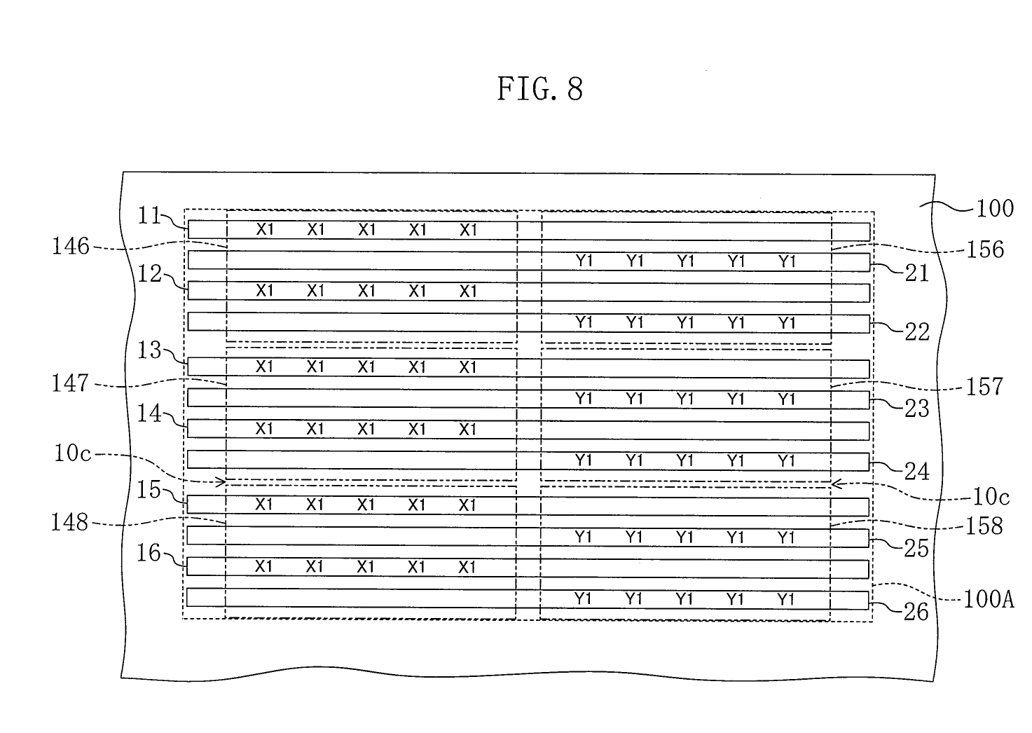

FIG. 8 is a plan view diagrammatically showing the positional relationship between the buses 146 to 148 and 156 to 158 shown in FIG. 7 and the underlying metal layer. Note that the buses 146 to 148 and 156 to 158 are shown by phantom lines in FIG. 8.

As shown in FIG. 8, under the buses 146 to 148 and 156 to 158 as the third-layer buses in this embodiment, formed alternately are source lines 11, 12, 13, 14, 15 and 16 (first metal patterns) and drain lines 21, 22, 23, 24, 25 and 26 (second metal patterns), both as the second-layer buses (second metal layer), which are arranged in lateral elongated stripes parallel to one another at a fixed pitch. The third-layer buses 146 to 148 are respectively connected to the source lines 11 and 12, 13 and 14, and 15 and 16 as the second-layer buses via a plurality of metal-filled vias X1. Likewise, the third-layer buses 156 to 158 are respectively connected to the drain lines 21 and 22, 23 and 24, and 25 and 26 via a plurality of metal-filled vias Y1.

As described above, in the semiconductor integrated circuit of Embodiment 4 of the present invention, the buses 146 to 148 and buses 156 to 158 respectively connected to the sources and drains of a power transistor are obtained by dividing large-size buses of the power transistor equally. One contact pad is in contact with each of these buses 146 to 148 and 156 to 158, and such contact pads 304 are located right above the power transistor. Thus, the stress applied to the metal layer of the large-size buses at wire bonding and at probing during testing is dissipated with the existence of the equally-divided buses separated with the slits 10c. This can suppress occurrence of warping that may occur in a large-area metal-layer bus susceptible to stress, and reduces stress on the entire power transistor. In this way, it is possible to prevent occurrence of warping in the vicinity of the top-layer buses formed under the contact pads 304 and thus prevent occurrence of cracking in an insulating film in the vicinity of the contact pads 304. As a result, the reliability of the semiconductor integrated circuit can be improved.

Also, as is apparent from the comparison of the semiconductor integrated circuit shown in FIG. 7 with the conventional semiconductor integrated circuit shown in FIG. 10, large buses are equally divided with the slits 10c to provide the top-layer buses 146 to 148 and 156 to 158 in the semiconductor integrated circuit of this embodiment shown in FIG. 7 while nothing special is devised in the top-layer buses in the power transistor in FIG. 10. This difference in configuration permits the semiconductor integrated circuit of this embodiment to produce the following effect that is unattainable in the conventional case. That is, since the stress applied at wire bonding or at probing during testing is dissipated to the equally divided buses 146 to 148 and 156 to 158, it is possible to suppress occurrence of warping in the vicinity of the top-layer buses formed under the contact pads 304 and thus prevent occurrence of cracking in an insulating film in the vicinity of the contact pads 304. As a result, the reliability of the semiconductor integrated circuit can be improved.

The present invention should not be construed as being restrictive to the embodiments described above. Various modifications and combinations of the illustrative embodiments, as well as other embodiments of the invention, will be apparent to those skilled in the art upon reference to the description. As an example, the present invention covers generally a semiconductor integrated circuit that includes contact pads located above active components, and the positions of these pads are selected so as to provide control and distribution of power to the active components under the pads. As another example, the present invention covers a semiconductor IC that includes contact pads located above active components, and these pads are placed to minimize the distance for power delivery between one selected pad and one or more corresponding active components to which the power is to be supplied. It is therefore intended that the appended claims encompass any such modifications and embodiments.

In the semiconductor integrated circuits and the fabrication methods for the same according to the present invention, the layout of a power integrated circuit in which wire bonding is executed right above an active circuit area using the POE technique is devised, to be contributive to both reduction in power consumption and improvement in reliability in the performance of key semiconductor electronic components such as power supplies, motor drivers and audio amplifiers. Accordingly, the present invention, which utilizes the existing facilities in fabrication, can be easily implemented at low cost, and thus is very useful for inexpensive, high-quality and high-performance power integrated circuits.

What is claimed is:

1. A semiconductor integrated circuit comprising:
an integrated power transistor formed on a semiconductor substrate;
an interlayer insulating film formed on the power transistor;
at least one or more first metal patterns made of a first metal layer formed inside the interlayer insulating film at a position right above the power transistor, for acting as a first electrode of the power transistor;
at least one or more second metal patterns made of the first metal layer for acting as a second electrode of the power transistor;
a single first bus made of a second metal layer formed inside the interlayer insulating film at a position right above the first metal layer, the first bus being electrically connected with the at least one or more first metal patterns;
a single second bus made of the second metal layer, the second bus being electrically connected with the at least one second metal patterns; and
one contact pad provided for each of the first bus and the second bus,
wherein each of the first bus and the second bus has at least one slit.

2. The circuit of claim 1, wherein at least one or more contact pads are provided for each of the first bus and the second bus.

3. The circuit of claim 1, wherein the power transistor is divided into a plurality of parts with an isolation layer.

4. The circuit of claim 1, wherein the slit is formed at edges of each of the first bus and the second bus.

5. The circuit of claim 1, wherein the slit is formed inside each of the first bus and the second bus.

6. The circuit of claim 1, wherein a plurality of slits are formed at edges of and inside each of the first bus and the second bus.

7. The circuit of claim 1, wherein each of the first bus and the second bus is divided into a plurality of parts with the slit,
one contact pad is formed on each of the plurality of divided buses, and
the size of the power transistor is equal to or greater than the size of each of the contact pads on each of the plurality of divided buses as is viewed from top.

8. A fabrication method for a semiconductor integrated circuit, comprising the steps of:
forming an integrated power transistor on a semiconductor substrate;
forming a first interlayer insulating film on the power transistor;
depositing a first metal layer right above the power transistor via the first interlayer insulating film and then patterning the first metal layer, to form at least one or more first metal patterns acting as a first electrode of the power transistor and at least one or more second metal patterns acting as a second electrode of the power transistor;
forming a second interlayer insulating film on the first interlayer insulating film so as to cover the at least one or more first metal patterns and the at least one or more second metal patterns;
depositing a second metal layer right above the first metal layer via the second interlayer insulating film and then patterning the second metal layer, to form a single first bus electrically connected with the at least one or more first metal patterns and having at least one strip and a single second bus electrically connected with the at least one or more second metal patterns and having at least one strip;
forming a third interlayer insulating film on the second interlayer insulating film so as to cover the first bus and the second bus;
forming one opening through the third interlayer insulating film for each of the first bus and the second bus so as to expose the first bus and the second bus;
placing a contact pad on each of the first bus and the second bus exposed in the opening; and
attaching at least one connection member to the contact pad.

9. The method of claim 8, wherein the step of forming one opening comprises the step of forming at least one or more openings through the third interlayer insulating film for each of the first bus and the second bus so as to expose the first bus and the second bus.
